(19) United States
(12) Patent Application Publication
(10) Pub. No.: US 2015/0115420 A1
(43) Pub. Date: Apr. 30, 2015

(54) SENSOR DIE GRID ARRAY PACKAGE

(71) Applicants: Navas Khan Oratti Kalandar, Petaling Jaya (MY); Kesvakumar V.C. Muniandy, Klang (MY)

(72) Inventors: Navas Khan Oratti Kalandar, Petaling Jaya (MY); Kesvakumar V.C. Muniandy, Klang (MY)

(21) Appl. No.: 14/069,358

(22) Filed: Oct. 31, 2013

(51) Int. Cl. H01L 23/495; H01L 21/56; H01L 21/48

(52) U.S. Cl. CPC H01L 23/49575; H01L 21/4825; H01L 21/561
USPC 257/666; 438/109

(57) ABSTRACT

A semiconductor sensor die grid array package includes a semiconductor die having an active surface and an opposite backside surface. The active surface has external die connection pads. Conductive runners respectively connect the die connection pads to external connection mounts of the package. An encapsulant covers the semiconductor die. The encapsulant has a base surface proximal to the conductive runners and a stacking surface opposite the base surface. A sensor die is supported on the stacking surface. The sensor die has an active surface and an opposite backside surface that faces the stacking surface, and the sensor active surface has sensor connection pads. Conductive vias engage with the conductive runners and also are wire bonded to one of the sensor connection pads.

### BACKGROUND OF THE INVENTION

The present invention relates generally to a semiconductor packaging and, more particularly, to a stacked die grid array package.

Semiconductor packaging provides external electrical connections and physical protection for packaged dies.

Continued progress in reduction of the size of the semiconductor dies and increased functionality and complexity of the electronic circuits integrated in the dies requires size reduction of the packaging with the same or greater complexity of the electrical connections with external circuits.

One typical package type is Quad Flat Pack (QFP) packages, which are formed with a semiconductor die mounted to a lead frame. The lead frame comprises a die attach pad often called a flag, leads that surround the flag, and arms that attach the flag to a frame, and is formed from a sheet of metal. Ends of the leads are electrically connected to electrodes of the die with bond wires to provide a means of easily electrically connecting the die to circuit boards and the like. After the electrodes and leads are connected, the die, bond wires, and leads are encapsulated with a plastic material leaving only sections of the leads exposed. These exposed leads are cut from the frame of the lead frame (singulated) and bent for ease of connection to a circuit board. However, the inherent structure of the QFP package limits the number of leads, and therefore the number of package external electrical connections, that can be used for a specific QFP package size.

Grid array packages have been developed as an alternative to QFP packages. Grid array packages increase the number of external electrical connections while maintaining or even decreasing the package size. Such grid array packages include Pin Grid Arrays (PGA), Ball Grid Array (BGA) and Land Grid Arrays (LGA).

When sensors such as pressure sensors are incorporated into a grid array package, the mounting surface area (footprint) may increase by at least the area of the active surface of the sensor. Stacking of a die and sensor die can reduce the mounting surface area, however, the active surface of the sensor must face away from the mounting surface and therefore the stacking of a die and sensor causes connectivity issues.

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of an electrically conductive sheet used for making a sensor die grid array package in accordance with a first preferred embodiment of the present invention;

FIG. 2 is a cross-sectional side view, through 2-2′, of the sheet of FIG. 1;

FIG. 3 is a cross-sectional side view of an etched sheet, formed from the sheet of FIG. 1, in accordance with a preferred embodiment of the present invention;

FIG. 4 is a plan view of a modified sheet of frames, formed from the sheet of FIG. 3, in accordance with a preferred embodiment of the present invention;

FIG. 5 is a cross-sectional side view of a modified frame through 5-5′, of the modified sheet of frames of FIG. 4;

FIG. 6 is an inverted cross-sectional side view of a populated frame assembly, formed from the modified frame of FIG. 5, in accordance with a preferred embodiment of the present invention;

FIG. 7 is a cross-sectional side view of a filled aperture populated frame assembly, formed from the populated frame assembly of FIG. 6, in accordance with a preferred embodiment of the present invention;

FIG. 8 is a cross-sectional side view of ground surface populated frame assembly, formed from the assembly of FIG. 7, in accordance with a preferred embodiment of the present invention;

FIG. 9 is an inverted cross-sectional side view of a sputter coated frame assembly, formed from the assembly of FIG. 8, in accordance with a preferred embodiment of the present invention;

FIG. 10 is a cross-sectional side view of a plated frame assembly, formed from the assembly of FIG. 9, in accordance with a preferred embodiment of the present invention;

FIG. 11 is a cross-sectional side view of an unmasked plated frame assembly, formed from the assembly of FIG. 10, in accordance with a preferred embodiment of the present invention;

FIG. 12 is a cross-sectional side view of an etched plated frame assembly, formed from the assembly of FIG. 11, in accordance with a preferred embodiment of the present invention;

FIG. 13 is a cross-sectional side view of a dielectric covered plated frame assembly, formed from the etched plated frame assembly of FIG. 12, in accordance with a preferred embodiment of the present invention;

FIG. 14 is a cross-sectional side view of a partially completed stacked sensor and semiconductor die grid array package, formed from the dielectric covered plated frame assembly of FIG. 13, in accordance with a preferred embodiment of the present invention;

FIG. 15 is an inverted cross-sectional side view of a dual surface plated frame assembly, formed from the package of FIG. 14, in accordance with the a embodiment of the present invention;

FIG. 16 is a cross-sectional side view of a dual wire bonded stacked sensor and semiconductor die assembly, formed from the assembly of FIG. 15, in accordance with a preferred embodiment of the present invention;

FIG. 17 is a cross-sectional side view of a stacked sensor and semiconductor die grid array package, formed from the die assembly of FIG. 16, in accordance with a preferred embodiment of the present invention;

FIG. 18 is a cross-sectional side view of a stacked sensor and semiconductor die grid array package, formed from the die assembly of FIG. 16, in accordance with another preferred embodiment of the present invention;

FIG. 19 is a cross-sectional side view of a stacked sensor and semiconductor die grid array package, formed from the package of FIG. 14, in accordance with another preferred embodiment of the present invention;

FIG. 20 is a cross-sectional side view of a stacked sensor and semiconductor die grid array package, in accordance with yet another preferred embodiment of the present invention; and

FIG. 21 is a flow chart illustrating a method for assembling a stacked sensor and semiconductor die grid array package.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a stacked sensor and semiconductor die grid array package. The package includes at least one semiconductor die having an active surface and an opposite other die surface, the active surface having external electrical die connection pads. Conductive runners respectively connect at least some of the die electrical connection pads to external connection mounts of the package. An encapsulating material at least partially encapsulates the semiconductor die. The encapsulating material has a base surface proximal to the conductive runners and a stacking surface opposite the base surface. A sensor is supported on the stacking surface. The sensor has a sensor active surface and an opposite sensor surface that faces the stacking surface, and the sensor active surface has external electrical sensor connection pads. There is at least one conductive via with a first end and a second end, the first end engages with one of the conductive runners and the second end is wire bonded to one of the external electrical sensor connection pads.

In another embodiment, the present invention provides a method for manufacturing a stacked sensor and semiconductor die grid array package. The method includes providing a conductive sheet that has a plurality of frames, each of the frames at least partially surrounding a respective aperture in sheet, wherein the apertures extend between opposed first and second surfaces of the each frame. The frame is processed to form conductive via members exposed at said first surface and extending towards said second surface, and the via members are with an insulating material. The method then performs a process of depositing, in each aperture, at least one semiconductor die, the die having an active surface and an opposite other die surface, and the die active surface having external electrical die connection pads.

An encapsulating material is deposited into the aperture and at least partially covers the semiconductor die. The encapsulating material has a base surface proximal to the first surface and a stacking surface opposite the base surface. Part of the frame is to expose the conductive vias at the second surface and the method performs a process of electrically connecting the external electrical die connection pads and the vias to conductive runners. At least some of the runners provide external connection mounts of the package and may also provide internal package interconnects. A sensor is mounted on the stacking surface. The sensor has a sensor active surface and an opposite sensor surface that faces the stacking surface, and wherein the sensor active surface has external electrical sensor connection pads. A wire bonding process is performed to electrically connect the external electrical sensor connection pads to the vias with bond wires.

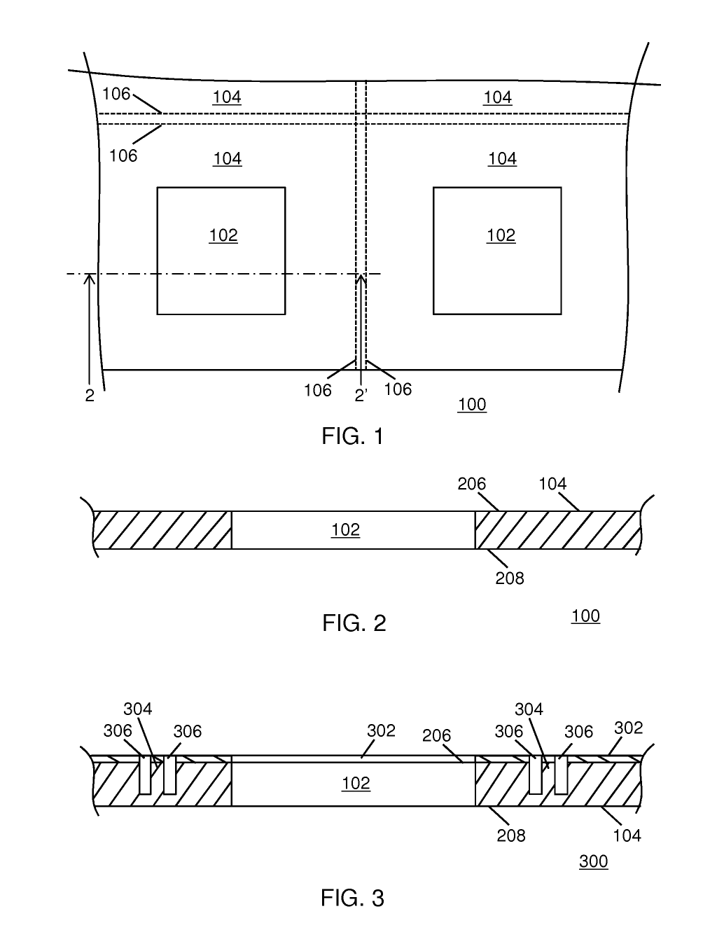

Referring now to FIG. 1, a plan view of an electrically conductive sheet 100 used for making a stacked sensor and semiconductor die grid array package, in accordance with a first preferred embodiment of the present invention, is shown. The electrically conductive sheet 100 is typically formed of metal such as copper or aluminum. The sheet 100 has an array of apertures 102 typically punched or cut into the sheet 100. Also, as will be apparent to a person skilled in the art, the sheet 102 is essentially a plurality of individual conductive frames 104 that will be eventually partitioned along singulation lines 106 which are indicated in phantom.

FIG. 2 illustrates a cross-sectional side view, through 2-2′, of the sheet 100. The frame 104 has opposed first and second surfaces 206, 208 and the aperture 102 extends between the surfaces 206, 208 such that each frame surrounds the aperture 102.

FIG. 3 shows a cross-sectional side view of an etched sheet 300, formed from the sheet 100, in accordance with a preferred embodiment of the present invention. The etched sheet 300 is the sheet 100 with a layer of photo-resist 302 applied to the first surface 206. The photo-resist 302 provides a mask that defines a conductive vias 304 and recessed surrounds 306. The recessed surrounds 306 are etched into the sheet 100 to define the conductive vias 304 in the form of pillars which are exposed at the first surface 206 and extend towards the second surface 208.

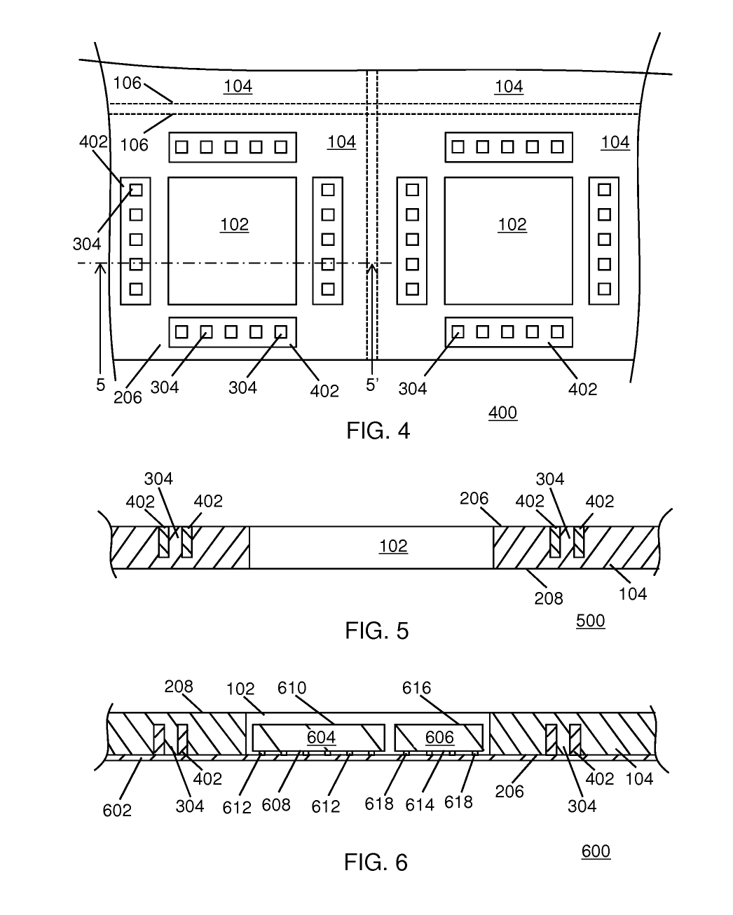

FIG. 4 illustrates a plan view of a modified sheet of frames 400, formed from the sheet 300, in accordance with a preferred embodiment of the present invention. The modified sheet of frames 400 includes the conductive vias 304 in respective insulated surrounds 402 and as shown the layer of photo-resist 302 has been removed. Also, a via insulating material 402, such as a dielectric or polymer, has been deposited into the recessed surrounds 306. The via insulating material 402 is typically deposited by a screen depositing process in which the insulating material 402 is pressed into the recessed surrounds 306. The insulating material 402 is cured and any excess material on the first surface 206 is then removed by a buffering roller.

Referring to FIG. 5, a cross-sectional side view of a modified frame 500, through 5-5′, of the modified sheet of frames 400 is shown. The conductive vias 304 in the form of pillars are still part of and attached to the frame 104.

In FIG. 6 there is illustrated an inverted cross-sectional side view of a populated frame assembly 600, formed from the modified frame 500, in accordance with a preferred embodiment of the present invention. The frame assembly 600 is the modified frame 500 when inverted and mounted on the first surface 206 to a carrier film 602. Deposited in the aperture 102 are a first semiconductor die 604 and a second semiconductor die 606 so that the frame 104 surrounds the dice 604, 606. The first semiconductor die 604 has a die active surface 608 and an opposite other die surface 610. The die active surface 608 has external electrical die connection pads 612 that abut the carrier film 602 and thereby support the first semiconductor die 604. Similarly, the second semiconductor die 606 has a die active surface 614 and an opposite other die surface 616. The die active surface 614 has external electrical die connection pads 618 that abut the carrier film 602 and thereby support the second semiconductor die 606.

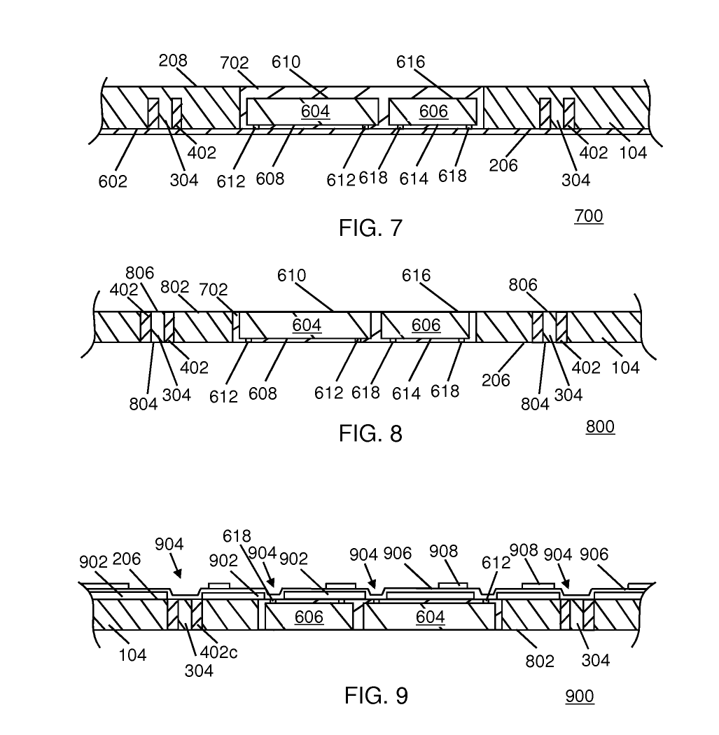

Referring to FIG. 7, a cross-sectional side view of filled aperture populated frame assembly 700, formed from the populated frame assembly 600, in accordance with a preferred embodiment of the present invention, is shown. The filled aperture populated frame assembly 700 is the populated frame assembly 600 with an encapsulating material 702 deposited into the aperture 102 and encapsulating the dies 604, 606. The encapsulating material 702 is typically a moisture resistant compound with electrically insulating properties that is moulded into the aperture 102.

FIG. 8 is a cross-sectional side view of ground surface populated frame assembly 800, formed from the assembly 700, in accordance with a preferred embodiment of the present invention. The assembly 800 is the filled aperture populated frame assembly 700 with the second surface 208 of the frame 104, and a surface of the encapsulating material 702, being etched or ground back to form a stacking surface 802. Thus, this etching or grinding back exposes the conductive vias 308 at the second surface 206 of the frame 104, and electrically isolates the vias 308 from each other so that the vias 308 have a first end 804 and a second end 806. Furthermore, the vias are electrically insulated from each other by the electrical insulating material 402 deposited in the recesses 306 formed in the frame 104. Also, as shown, the assembly 800 has had the carrier film 602 removed (typically by peeling) so that a process of splutter coating can be performed typically by a redistribution chip process to provide distribution conducive runners.

FIG. 9 shows an inverted cross-sectional side view of a sputter coated frame assembly 900, formed from the assembly of FIG. 8, in accordance with a preferred embodiment of the present invention. The sputter coated frame assembly 900 is the ground surface populated frame assembly 800 with a insulating redistribution layer or dielectric mask 902 that has been deposited on the first surface 206 and areas of the encapsulating material 702. Exposed regions 904 of the dielectric mask 902 are aligned with the conductive vias 304 and the external electrical die connection pads 612, 618.

The sputter coated frame assembly 900 has partially formed electrically conductive runners (sputter coating) 906 deposited over the mask 902 and the exposed regions 904. The sputter coatings 906, in the exposed regions 904, form electrical contacts with the respective conductive vias 304 and the external electrical die connection pads 612, 618. There is also a sacrificial plating mask 908 positioned over regions of the sputter coating 906 that are required to be removed.

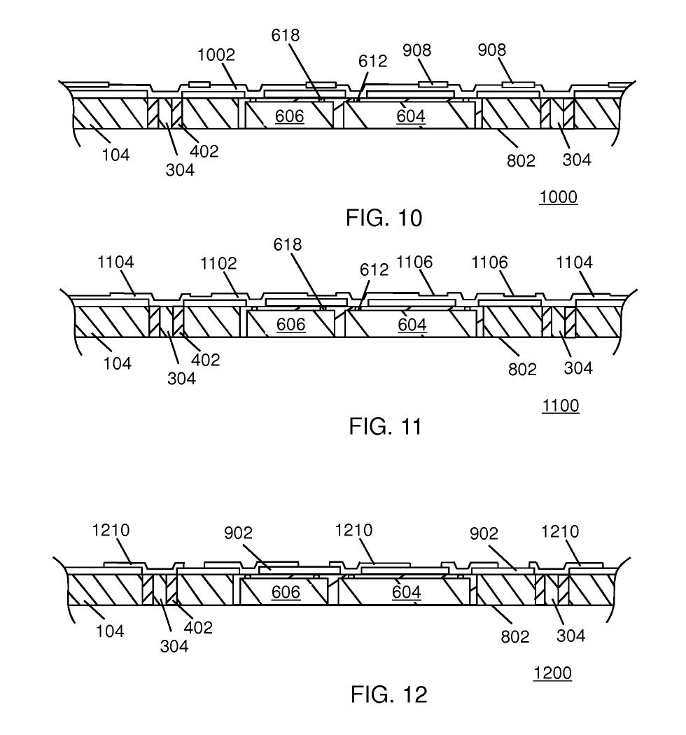

Referring to FIG. 10 there is illustrated a cross-sectional side view of a plated frame assembly 1000, formed from the assembly 900, in accordance with a preferred embodiment of the present invention. The assembly 1000 is the sputter coated frame assembly 900 with a plating 1002, such as a copper plating, deposited in exposed regions of the sacrificial plating mask 908.

FIG. 11 is a cross-sectional side view of an unmasked plated frame assembly 1100, formed from the assembly 1000, in accordance with a preferred embodiment of the present invention. The unmasked plated frame assembly 1100 is the assembly 1000 after an etching or stripping process has removed the sacrificial plating mask 908. As shown, there is an uneven covering of an electrically conductive deposit 1102. This electrically conductive deposit 1102 includes thicker regions 1004 typically of 12 microns provided by a combination of the sputter coating 906 and plating 1002, and thinner regions 1106 typically of 2 microns provided by the sputter coating 906.

Referring to FIG. 12 there is illustrated a cross-sectional side view of an etched plated frame assembly 1200, formed from the assembly 1100, in accordance with a preferred embodiment of the present invention. The etched plated frame assembly 1200 is the assembly 1100 after an etching process has removed about 3 microns of the electrically conductive deposit 1102. As a result, the electrically conductive deposit 1102 forms numerous redistribution electrically conductive runners 1210 having, in this embodiment, a thickness of about 9 microns. However, the runners 1210 may have any suitable thickness as will be apparent to a person skilled in the art.

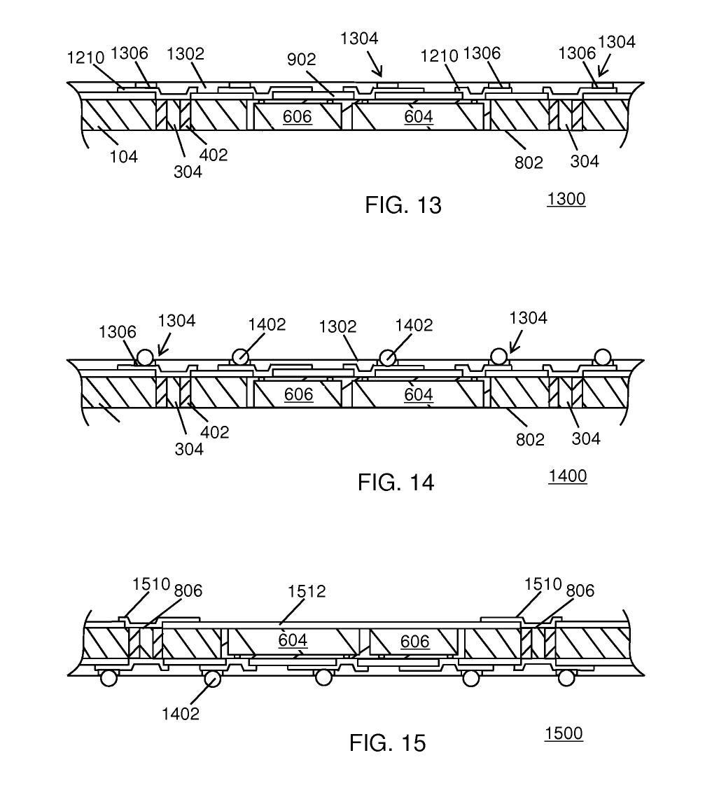

FIG. 13 is a cross-sectional side view of a dielectric covered plated frame assembly 1300, formed from the etched plated frame assembly 1200, in accordance with a preferred embodiment of the present invention. The dielectric covered plated frame assembly 1300 has a dielectric covering 1302 that selectively covers and insulates the electrically conductive runners 1210 and dielectric mask 902. Apertures 1304 in the dielectric covering 1302 allow external access to the sections of the electrically conductive runners 1210 that provide external connector contacting areas 1306. Thus, the runners 1210 provide selective electrical connectivity between: the areas 1306 and the conductive vias 304; and areas 1306 and the external electrical die connection pads 612, 618. It will also be apparent to a person skilled in the art that the runners 1210 may also provide internal connectivity between: the first and second semiconductor dice 604, 606; and between the one or more of the conductive vias 304 and one of the semiconductor dice 604, 606.

Referring to FIG. 14, a cross-sectional side view of a partially completed stacked sensor and semiconductor die grid array package 1400, formed from the dielectric covered plated frame assembly 1300, in accordance with a preferred embodiment of the present invention, is shown. The package 1400 has external electrical connectors in the form of solder balls 1402 each deposited in one of the apertures 1304 and mounted to a designated external connector contacting area 1306. Once the solder balls 1402 are mounted a ball grid array is formed as will be apparent to a person skilled in the art.

FIG. 15 is an inverted cross-sectional side view of a dual surface plated frame assembly 1500, formed from the package 1400, in accordance with a preferred embodiment of the present invention. The assembly 1500 has additional conductive runners 1510 deposited by the redistribution chip process as described above in FIGS. 9 to 12. The conductive runners 1510 have regions deposited on a dielectric mask 1512. The additional conductive runners 1510 are also electrically connected to a respective second ends 806 of the conductive vias 304.

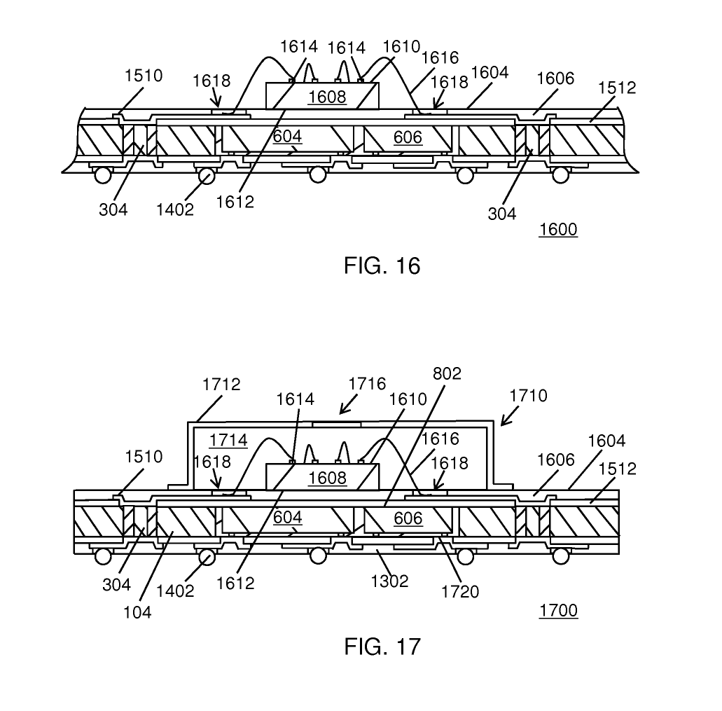

Referring to FIG. 16, a cross-sectional side view of a dual wire bonded stacked sensor and semiconductor die assembly 1600, formed from the assembly 1500, in accordance with a preferred embodiment of the present invention, is shown. The assembly 1600 has a sensor supporting surface 1604 which is an outer surface of a dielectric covering 1606 deposited over the stacking surface 802. A sensor 1608 is mounted to the sensor supporting surface 1604. The sensor 1608 has a sensor active surface 1610 and an opposite sensor surface 1612 that faces the sensor supporting surface 1604.

The sensor active surface 1610 has external electrical sensor connection pads 1614 that wire bonded, with bond wires 1616, to respective conductive runners 1510. In this regard apertures 1618 in the dielectric covering 1606 allow the bond wires 1616 access to the respective conductive runners 1510. The sensor 1608 is typically a pressure or optical sensor but any ambient condition senor can be used. Also, the first semiconductor die 604 is typically a microcontroller and the second semiconductor die 606 may typically be an accelerometer.

Referring to FIG. 17, a cross-sectional side view of a stacked sensor and semiconductor die grid array package 1700, formed from the die assembly 1600, in accordance with a first preferred embodiment of the present invention, is shown. The package 1700 has been formed from separating the frames 104 along the singulation lines 106 of the sheet 100. The package 1700 is the singulated assembly 1600 with a protective covering 1710 that covers and protects the sensor active surface 1610, external electrical sensor connection pads 1614 and bond wires 1616. The covering 1710 includes a lid 1712 mounted to the dielectric covering 1606. The lid 1712 has a chamber filled with a non-electrically conductive gel 1714 that is typically a transparent silicon based gel, and the lid 1712 has an aperture 1716 that provides a widow for the sensor to detect ambient conditions outside the lid 1712.

In summary the stacked sensor and semiconductor die grid array package 1700 includes the semiconductor dice 604, 606 with and the encapsulating material 702 encapsulating edges of the dice 604, 606. The encapsulating material 702 has a base surface 1720 proximal to the conductive runners 1210 and covering 1302 and an opposite second surface which is the stacking surface 802. As will be apparent to a person skilled in the art, both the sensor 1608 and lid 1712 are supported on the stacking surface 802, but spaced from the stacking surface 802, by the dielectric covering 1606 and dielectric mask 1512. Also, as illustrated, the first end 804 of a respective conductive via 304 engages with one of the runners 1210. Furthermore, the second end 806 of each via 304 is wire bonded to one of the external electrical sensor connection pads 1614 of the sensor 1608.

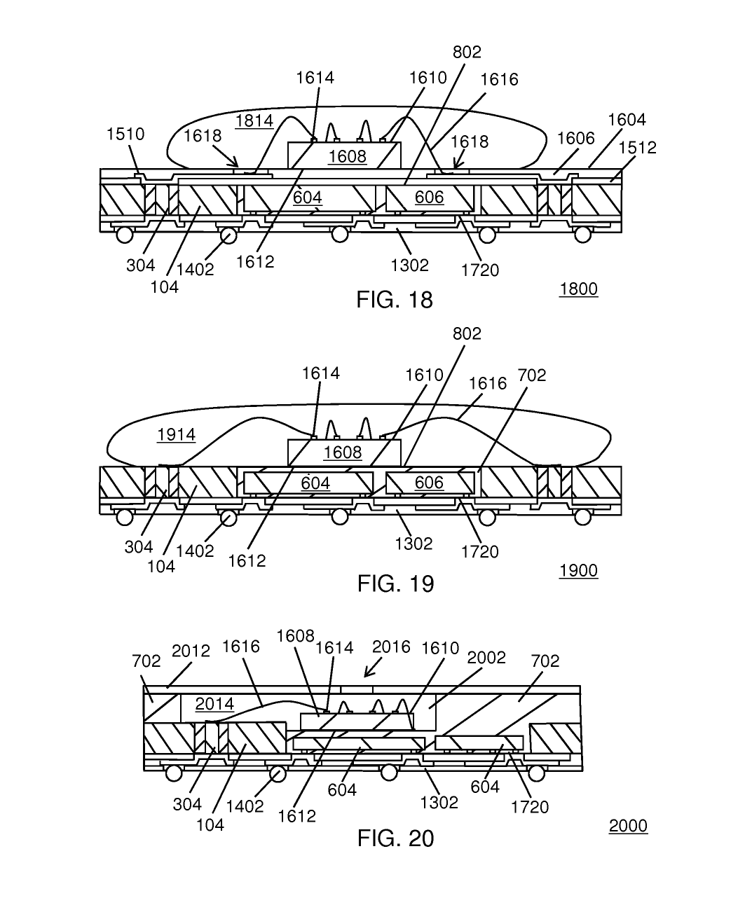

Referring to FIG. 18, a cross-sectional side view of a stacked sensor and semiconductor die grid array package 1800, formed from the die assembly 1600, in accordance with a second preferred embodiment of the present invention, is shown. The stacked sensor and semiconductor die grid array package 1800 is similar to the package 1700 and to avoid repetition only the differences will be described. The stacked sensor and semiconductor die grid array package 1800 has a protective covering in the form of a non-electrically conductive gel 1814. The gel 1841 is self-affixing, by its adhesive properties, to the dielectric covering 1606 and provides a covering and protection to the sensor active surface 1610, external electrical sensor connection pads 1614 and bond wires 1616.

FIG. 19 illustrates a cross-sectional side view of a stacked sensor and semiconductor die grid array package 1900, formed from the grid array package 1400, in accordance with a third preferred embodiment of the present invention. The stacked sensor and semiconductor die grid array package 1800 is similar to the package 1800 and to avoid repetition only the differences will be described. In this embodiment there is no dielectric mask 1512, conductive runners 1510 or dielectric covering 1606. Consequently, the sensor 1608 is mounted directly onto the stacking surface 802 encapsulating material 702. Also, the external electrical sensor connection pads 1614 are wire bonded directly to respective second ends 806 of the vias 304. The stacked sensor and semiconductor die grid array package 1900 has a protective covering in the form of a non-electrically conductive gel 1914. The gel 1941 is self-affixing, by its adhesive properties, to the dielectric covering frame 104 and encapsulating material 702. Also, the external electrical sensor connection pads 1614 provide a covering and protection for the sensor active surface 1610, external electrical sensor connection pads 1614 and bond wires 1616.

Referring to FIG. 20, a cross-sectional side view of a stacked sensor and semiconductor die grid array package 2000, in accordance with a fourth preferred embodiment of the present invention is shown. The stacked sensor and semiconductor die grid array package 1900 is similar to the package 1800 and to avoid repetition only the differences will be described. In this embodiment the encapsulating material 702 covers part of the second surface 208 of the frame 104 thereby providing a chamber 2002 filled with a protective covering in the form of a non-electrically conductive gel 2014 and lid 2012 with an aperture 2016. The lid 2012 is a planar sheet mounted directly onto the encapsulating material 702 and both the lid 2012 and gel 2014 provide a covering and protection for the sensor active surface 1610, external electrical sensor connection pads 1614 and wire bonds 1616.

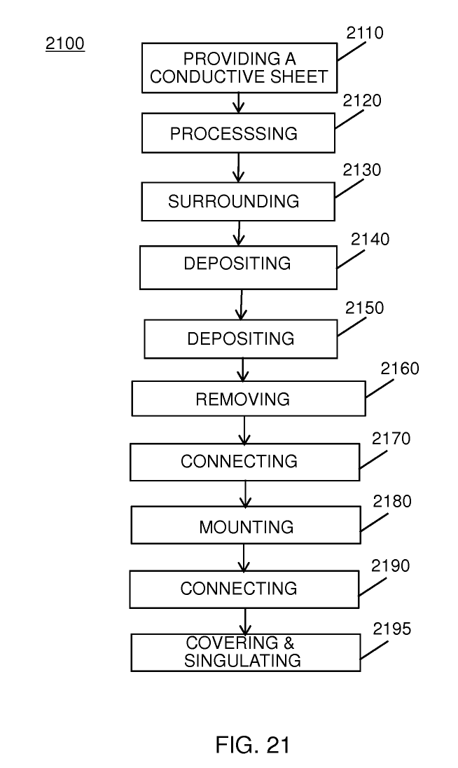

FIG. 21 is a flow chart illustrating a method 2100 for manufacturing a stacked sensor and semiconductor die grid array package in accordance with a preferred embodiment of the present invention. By way of explanation only, the method 2100 will be described with particular reference to FIGS. 1 to 17. At a providing block 2110, the conductive sheet 100 is provided and the frames 104, at a processing block 2120, are processed to form the conductive via members 304. The frames 104 are processed by applying the mask of photo-resist 302 to the first surface 206 of each the frame 104 and then an etching process etches recesses 306 in the first surface 206 to provide spaced pillars in the frame at exposed regions of the mask of photo-resist 302. The insulating material 402 is then deposited in the recesses 306.

At a surrounding block 2130, the vias 304 are surrounded with the insulating material 402. At a depositing block 2140, the semiconductor dies 604, 606 are deposited on top of the carrier film 606 in the apertures 102 and at a block 2150 the encapsulating material 702 is deposited into the apertures 102. When so deposited, by a molding process, the encapsulating material 702 has a base surface proximal to the first surface 206 and a stacking surface opposite the base surface.

At a removing block 2160, part of each of the frames 104 is removed by grinding to expose the conductive vias at the second surface 208 and then, at a block 2170, the external electrical die connection pads 612, 618 and the vias 304 are electrically connected to the conductive runners 1210. The conductive runners 1210 are formed from the redistribution layer process. This process forms the conductive runners 1210 from the plated sputter coating 906 that is at least partially insulated by the redistribution layer or dielectric mask 902. If required, the solder balls 1402 are then mounted to a designated external connector contacting area 1306 of a respective one of the conductive runners 1210.

Next, at a mounting block 2180 the sensor 1608 is mounted on the stacking surface 802 and the external electrical sensor connection pads 1614 are electrically connected to respective vias 304 by the bond wires 1616 at a connecting block 2190. Finally, the gel 1714 and lid 712 are mounted or attached and the package is singulated at a block 2195.

Advantageously, the present invention provides a potentially reduced mounting surface area for a stacked sensor and semiconductor die grid array package. This is because the sensor is stacked on top of the semiconductor die or dice and the sensor active surface faces away from the grid array structure (mounting surface area) that includes the runners 1210 and covering 1302.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A sensor die grid array package, comprising:
at least one semiconductor die having an active surface and an opposite other die surface, the active surface having external electrical die connection pads;
conductive runners respectively connecting at least some of the die electrical connection pads to external connection mounts of the package;
an encapsulating material at least partially covering the semiconductor die, the encapsulating material having a base surface proximal to the conductive runners and a stacking surface opposite the base surface;
a sensor supported on the stacking surface, the sensor having a sensor active surface and an opposite sensor surface that faces the stacking surface, the sensor active surface having external electrical sensor connection pads; and
at least one conductive via having a first end and a second end, the first end engaging with one of the conductive runners and the second end being electrically connected to one of the external electrical sensor connection pads with a bond wire.

2. The sensor die grid array package of claim 1, further comprising a conductive frame at least partially surrounding the semiconductor die.

3. The sensor die grid array package of claim 2, further comprising a lid with a window therein, the lid being mounted directly to the encapsulating material and providing a covering to the sensor active surface, the external electrical sensor connection pads and bond wires.

4. The sensor die grid array package of claim 3, wherein the lid is a planar sheet.

5. The sensor die grid array package of claim 2, wherein the conductive via is formed from the frame.

6. The sensor die grid array package of claim 5, wherein the conductive via is electrically insulated with an insulating material.

7. The sensor die grid array package of claim 6, wherein the insulating material is deposited in a recess formed in the frame.

8. The sensor die grid array package of claim 1, further comprising a protective covering that covers the sensor active surface, the external electrical sensor connection pads and the bond wire.

9. The sensor die grid array package of claim 8, wherein the covering includes a non-electrically conductive gel.

10. The sensor die grid array package of claim 8, wherein the covering includes a lid with a window therein.

11. The sensor die grid array package of claim 10, wherein the lid has a chamber filled with a non-electrically conductive gel.

12. A method for assembling a semiconductor sensor die grid array package, comprising:
providing a conductive sheet that has a plurality of frames, each of the frames at least partially surrounding a respective aperture in the sheet, wherein the apertures extend between opposed first and second surfaces of each of the frames;
forming conductive vias in the frames, wherein the vias are exposed at said first surface and extending towards said second surface;
surrounding the vias with an insulating material;
depositing in each aperture at least one semiconductor die, the die having an active surface and an opposite other die surface, the die active surface having external electrical die connection pads;
depositing an encapsulating material in the aperture, the encapsulating material at least partially covering the semiconductor die, the encapsulating material having a base surface proximal to the first surface and a stacking surface opposite the base surface;
removing parts of the frames to expose the vias at the second surface;
electrically connecting the external electrical die connection pads and the vias to conductive runners at least some of which provide external connection mounts of the package;
mounting a sensor on the stacking surface, the sensor having a sensor active surface and an opposite sensor surface that faces the stacking surface, wherein the sensor active surface has external electrical sensor connection pads; and
electrically connecting the external electrical sensor connection pads to respective ones of said vias with bond wires.

13. The method of claim 12, further including placing a cover over the sensor active surface, the external electrical sensor connection pads and the bond wires.

14. The method of claim 13, wherein the cover includes a non-electrically conductive gel.

15. The method of claim 14, wherein the cover includes a lid with a window therein.

16. The method of claim 12, wherein the forming the conductive vias includes:
applying a mask to the first surfaces of the frames;
etching one or more recesses in the first surfaces to provide spaced pillars in the frames at exposed regions of the mask; and
depositing an insulating material in the recesses.

17. The method of claim 12, wherein the conductive runners are formed using a redistribution layer process resulting in the conductive runners being insulated with an insulating redistribution layer.

18. The method of claim 17, wherein the conductive runners are formed from a plated sputter coating.

19. The method of claim 12, further including mounting solder balls to a designated external connector contacting area of a respective one of the conductive runners.

20. The method of claim 12, further including forming additional conductive runners proximal to the second surface, the additional conductive runners being formed with a redistribution layer process, wherein the additional conductive runners are coupled to respective ones of the vias and selectively attached to ones of the bond wires.
